(19) United States
(12) Patent Application Publication
(10) Pub. No.: US 2024/0186168 A1
(43) Pub. Date: Jun. 6, 2024

(54) PROCESS FOR MANUFACTURING SEMICONDUCTOR WAFERS CONTAINING A GAS-PHASE EPITAXIAL LAYER IN A DEPOSITION CHAMBER

(71) Applicant: SILTRONIC AG, Munich (DE)

(72) Inventor: Thomas Stettner, Waging am See (DE)

(21) Appl. No.: 18/554,226

(22) PCT Filed: Mar. 31, 2022
(86) PCT No.: PCT/EP2022/058564

§ 371 Date: Oct. 6, 2023

(30) Foreign Application Priority Data
Apr. 13, 2021 (EP) 21168164.8

(51) Int. Cl. H01L 21/68; H01L 21/02

(52) U.S. Cl. CPC H01L 21/68; H01L 21/02381; H01L 21/0262

(57) ABSTRACT

A process produces semiconductor wafers with epitaxial layer deposited from a gas phase in a deposition chamber. The process includes placing a substrate wafer on a susceptor with circular perimeter by a robot that moves the substrate wafer into a placement position and places it on the susceptor with a corrective precept causing a center of the substrate wafer not to lie above a center of the susceptor; and depositing the epitaxial layer on the substrate wafer. A first number of substrate wafers having a specific resistance which falls within a first range are moved into the placement position with a first corrective precept, and a second number of substrate wafers having a specific resistance which falls within a second range are moved by the robot with a second corrective precept, differs from the first corrective precept.

### CROSS REFERENCE TO RELATED APPLICATIONS

This application is a U.S. National Phase application under 35 U.S.C. § 371 of International Application No. PCT/EP2022/058564, filed on Mar. 31, 2022, and claims benefit to European Patent Application No. EP 21168164.8, filed on Apr. 13, 2021. The International Application was published in German on Oct. 20, 2022 as WO 2022/128720 A1 under PCT Article 21(2).

### FIELD

The present disclosure relates to a process for producing semiconductor wafers with epitaxial layer deposited from the gas phase in a deposition chamber.

### BACKGROUND

Semiconductor wafers with an epitaxial layer are required for the production of electronic components. The epitaxial layer is typically deposited in a deposition chamber, which takes the form of a single-wafer reactor. The substrate wafer to be coated is placed on a susceptor, and a deposition gas is passed at a deposition temperature through the deposition chamber over the substrate wafer, which rotates with the susceptor.

One quality criterion of semiconductor wafers with an epitaxial layer is the edge geometry, especially the uniformity of the thickness of the epitaxial layer in the edge region of the semiconductor wafer.

JP 2016 213 218 A describes a process for producing semiconductor wafers of monocrystalline silicon with epitaxial layer from monocrystalline silicon. It is recommended that a robot which places the substrate wafer onto the susceptor of a deposition reactor is moved to a placement position in which, owing to a corrective precept, the center of the substrate wafer does not lie above the center of the susceptor. It has been found that otherwise the substrate wafers on average do not lie centered on the susceptor during the deposition of the epitaxial layer. If the substrate wafer is not located concentrically in the pocket of the susceptor during the deposition of the epitaxial layer, there is an adverse effect on the uniformity of the thickness of the epitaxial layer. Furthermore, any such positional deviation may result in unwanted formation of particles, particularly if it entails contact of the edge of the substrate wafer with the susceptor. The corrective precept is derived from an average which describes the mean deviation of the position of the center of substrate wafers from the center of the susceptor during preceding coating operations. Linked with the corrective precept is the expectation of achieving, during a coating operation, a position of the center of the substrate wafer that is closer, by the amount of the mean deviation, to the center of the susceptor than if there had been no corrective precept.

### SUMMARY

In an embodiment, the present disclosure provides a process that produces semiconductor wafers with epitaxial layer deposited from a gas phase in a deposition chamber. The process includes placing a substrate wafer on a susceptor with circular perimeter by a robot, where the robot moves the substrate wafer into a placement position and places it on the susceptor, with a corrective precept causing a center of the substrate wafer not to lie above a center of the susceptor in the placement position; and depositing the epitaxial layer on the substrate wafer. A first number of substrate wafers having a specific resistance which falls within a first range are moved into the placement position by the robot with a first corrective precept, and a second number of substrate wafers having a specific resistance which falls within a second range are moved into the placement position by the robot with a second corrective precept. The first corrective precept and the second corrective precept differ from one another.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows in a sectional representation an apparatus for depositing an epitaxial layer from the gas phase onto a substrate wafer;

FIG. 2 shows the positions of a first and second average value of positional deviations of substrate wafers of two different resistance ranges relative to the center of the susceptor;

FIG. 3 shows the distribution of the centers of substrate wafers having a resistance in a first range after placement on the susceptor relative to the center of the susceptor in a polar coordinate lattice; and

FIG. 4 shows the distribution of the centers of substrate wafers having a resistance in a second range after placement on the susceptor relative to the center of the susceptor in a polar coordinate lattice.

### DETAILED DESCRIPTION

The inventors of the present disclosure have determined that a specification of the corrective precept which is guided solely by the positional deviation during preceding coating operations is deserving of improvement.

The present disclosure therefore provides such an improvement.

The present disclosure provides a process for producing semiconductor wafers with epitaxial layer deposited from the gas phase in a deposition chamber, comprising
the placement of a substrate wafer on a susceptor with circular perimeter by a robot, where the robot moves the substrate wafer into a placement position and places it on the susceptor, with a corrective precept causing the center of the substrate wafer not to lie above the center of the susceptor in the placement position; and
the deposition of an epitaxial layer on the substrate wafer, wherein
a first number of substrate wafers having a specific resistance which falls within a first range are moved into the placement position by the robot with a first corrective precept, and a second number of substrate wafers having a specific resistance which falls within a second range are moved into the placement position by the robot with a second corrective precept, where the first and second corrective precepts differ from one another.

The implementation of the present disclosure takes account of the finding that the extent of any possible mispositioning of the substrate wafer during the deposition of the epitaxial layer is dependent on factors including the properties of the substrate, especially on the fraction of dopant in the substrate and on the resultant specific electrical resistance of the substrate (referred to for short below as resistance). It is therefore proposed according to the disclosure that the corrective precept be considered as a function of the resistance of the substrate wafer and that, for a substrate wafer having a resistance which falls within a first range, a first corrective precept is provided which deviates from a second corrective precept for a substrate wafer having a specific resistance which falls within a second range. The first and second ranges are disjoint, meaning that a particular resistance is not located simultaneously in the first range and in the second range.

The first corrective precept is calculated as an average value which describes the mean deviation of the position of the center of substrate wafers from the center of the susceptor during preceding coating operations, considering only those substrate wafers whose resistance falls within the first range. Correspondingly, the second corrective precept is calculated as an average value which describes the mean deviation of the position of the center of substrate wafers from the center of the susceptor during preceding coating operations, considering only those substrate wafers whose resistance falls within the second range. For substrate wafers having a resistance in a different range, which is disjoint to the first and second ranges, correspondingly, a different corrective precept is calculated, which is different from the first and second corrective precepts.

For the calculation of the average value (arithmetic mean), positional deviations of preferably at least 10, more preferably at least 20, substrate wafers are included, which have been coated preferably immediately before the substrate wafer to be coated, and which have a resistance in the range of the resistance of the substrate wafer to be coated.

Substrate wafers on which an epitaxial layer is deposited in accordance with the present disclosure are semiconductor wafers which comprise a dopant, preferably substrate wafers made of monocrystalline silicon.

Aspects of the present disclosure are described in more detail below with reference to drawings.

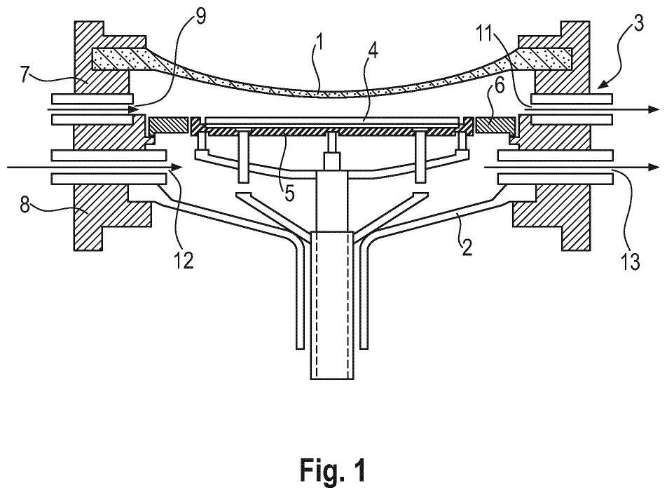

The apparatus shown in FIG. 1 for depositing an epitaxial layer on a substrate wafer comprises a deposition chamber 3 having an upper cover 1 and a lower cover 2, and upper and lower linings 7 and 8, which enclose a reaction space. Upper and lower lamp arrays may be present outside the deposition chamber 3. The radiant energy of the lamps brings the deposition chamber to the temperature which is needed for the gas-phase (vapor) deposition.

For a coating operation, a substrate wafer 4 is placed on a susceptor 5, which is held rotatably from below by arms of a carrier. Beforehand the substrate wafer is placed onto an end effector of a robot and is moved by the robot to a placement position. Arranged around the susceptor is a preheat ring 6. The substrate wafer 4 can be placed on the susceptor 5 and, after coating, lifted off from the susceptor 5 by means of lifting pins which go through the susceptor 5.

In the coating of the substrate wafer 4, deposition gas is passed through upper gas entry apertures 9, provided in the upper lining 7, into the deposition chamber 3 along a flow direction over the substrate wafer to an upper gas outlet 11. Optionally, furthermore, lower gas entry apertures 12 and a lower gas outlet 13 may be provided, in order for a purge gas to be passed under the susceptor 5 through to the lower gas outlet 13.

If the placement position for the robot is established such that the center of the substrate wafer lies perpendicularly above the center of the susceptor, there is a comparatively high probability that after the substrate wafer has been placed, its center will not lie in the center of the susceptor. The particular reason for this are thermal stresses, which resolve, causing the center of the substrate wafer to be shifted from the intended position.

It has now been found that the greater the amount of dopant contained in the substrate wafers, the larger the amount of the shift from the center of the susceptor, this amount therefore increasing as the resistance of the substrate wafers drops. In accordance with the present disclosure, this finding is taken into account when calculating the corrective precept which codetermines the placement position into which the robot moves a substrate wafer before it is placed onto the susceptor. The corrective precept is calculated by averaging from positional deviations of previously coated substrate wafers, with the data used for the averaging being only those data from substrate wafers whose resistance is approximately the same, thus lying within the same predetermined range. The concept of positional deviation describes the deviation in the position of the center of a placed substrate wafer relative to the center of the susceptor. For a substrate wafer to be coated, the corrective precept used by the robot is that which has been calculated for the resistance of this substrate wafer. A first range with comparatively high resistance may comprise, for example, 11 to 12 ohmcm, while a second range with comparatively low specific resistance may comprise, for example, 9 to 10 ohmcm.

Without the proposed resistance-dependent averaging, averaging of the positional deviations would result in a corrective precept which would be less accurate, since the influence of the resistances would be averaged out. The corrective precept ought, however, to be extremely precise, because a centered position of the substrate wafer on the susceptor has advantageous consequences for the edge geometry with the resultant semiconductor wafer with epitaxial layer and there is also a decrease in the risk of particles being generated during the deposition of the epitaxial layer.

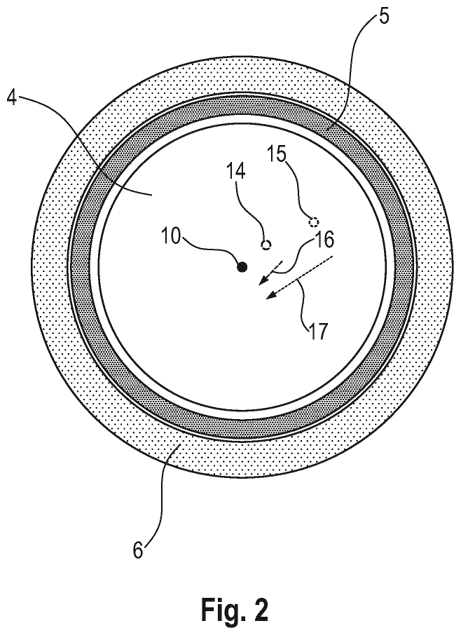

FIG. 2 shows a substrate wafer 4 which is placed on a susceptor 5, so that the center 10 of the susceptor 5 is coincident with the center of the substrate wafer 4. In this target position, the substrate wafer 4 is concentric with respect to the susceptor 5 and to the preheat ring 6. Without a corrective precept, the center of the substrate wafer, depending on its specific resistance, would lie on or in the vicinity of the average position which has been calculated for its resistance range—for example, on or in the vicinity of the first average position 14 in the case of a comparatively high specific resistance, or on or in the vicinity of the second average position 15 in the case of a specific resistance which is comparatively low. In the drawing, the positions 14 and 15 lie an unrealistic distance away from the center 10 of the susceptor, in order to be able to illustrate the present disclosure. In actual fact, typical positional deviations are not more than 1000 μm distant from the center 10 of the susceptor.

A distance between the first average position 14 and the center 10 of the susceptor 5 corresponds to the length of the vector 16. A distance between the second average position 15 and the center 10 of the susceptor 5 corresponds to the length of the vector 17. If the vector 16 or the vector 17 is shifted, so that its start is coincident with the center 10 of the susceptor, the point of the vector points to the placement position into which the robot is required to move the substrate wafer with its center in order to compensate for an anticipated positional deviation. The vectors 16 and 17 therefore represent possible corrective precepts for the robot.

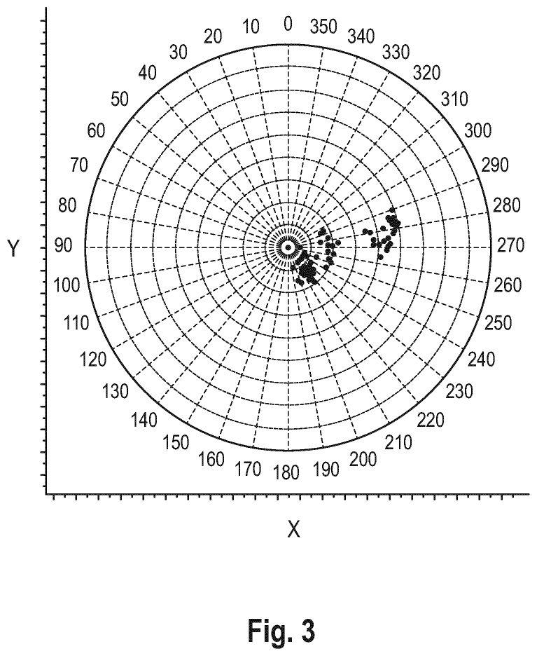

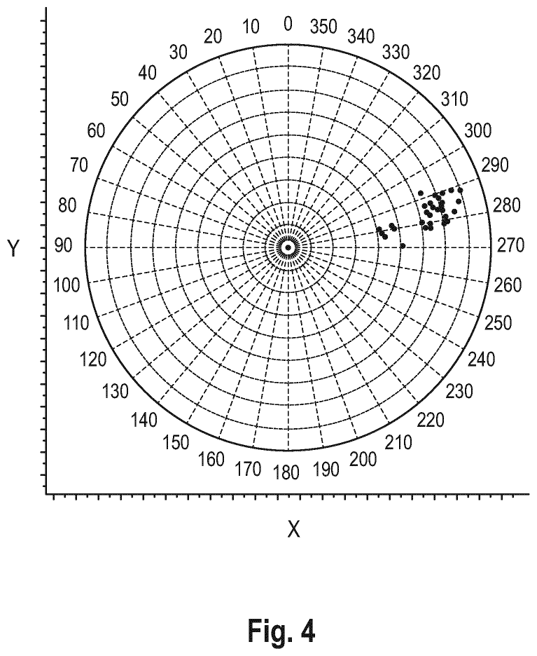

For a resistance range of 11-12 ohmcm and, respectively, for a resistance range of 9-10 ohmcm, FIG. 3 and FIG. 4 show measured positional deviations of boron-doped substrate wafers made of monocrystalline silicon having a diameter of 300 mm in a polar coordinate lattice. The comparison of the depicted distributions of the positional deviations makes it clear that the amount of the positional deviation is dependent on the dopant fraction.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS USED

1 upper cover
2 lower cover
3 deposition chamber
4 substrate wafer
5 susceptor
6 preheat ring
7 upper lining
8 lower lining
9 upper gas entry apertures
10 center of the susceptor
11 upper gas outlet
12 lower gas entry apertures
13 lower gas outlet
14 first average position of the center of placed substrate wafers
15 second average position of the center of placed substrate wafers
16 vector
17 vector

1. A process for producing semiconductor wafers with epitaxial layer deposited from a gas phase in a deposition chamber, the process comprising:
placing a substrate wafer on a susceptor with circular perimeter by a robot, where the robot moves the substrate wafer into a placement position and places it on the susceptor, with a corrective precept causing a center of the substrate wafer not to lie above a center of the susceptor in the placement position; and
depositing the epitaxial layer on the substrate wafer, wherein;
a first number of substrate wafers having a specific resistance which falls within a first range are moved into the placement position by the robot with a first corrective precept, and a second number of substrate wafers having a specific resistance which falls within a second range are moved into the placement position by the robot with a second corrective precept, where the first corrective precept and the second corrective precept differ from one another.

2. The process as claimed in claim 1, wherein an amount of the first corrective precept is larger or smaller than an amount of the second corrective precept, depending on whether a first range covers a specific resistance which is smaller or larger than a specific resistance which is covered by the second range.
